(19) United States
(12) Patent Application Publication
(10) Pub. No.: US 2025/0366198 A1
(43) Pub. Date: Nov. 27, 2025

(54) SEMICONDUCTOR DEVICE STRUCTURE FOR CHIP IDENTIFICATION

(71) Applicant: Taiwan Semiconductor Manufacturing Company, Ltd., Hsinchu (TW)

(72) Inventors: Bo-Huan HSIN, Taichung City (TW); Ying-Han CHIOU, Tainan City (TW)

(73) Assignee: Taiwan Semiconductor Manufacturing Company, Ltd., Hsinchu (TW)

(21) Appl. No.: 19/293,350

(22) Filed: Aug. 7, 2025

Related U.S. Application Data
(63) Continuation of application No. 18/516,478, filed on Nov. 21, 2023.
(60) Provisional application No. 63/518,031, filed on Aug. 7, 2023.

(51) Int. Cl. H10D 84/85; H10D 30/69; H10D 62/10; H10D 62/13

(52) U.S. Cl. CPC H10D 84/856; H10D 30/751; H10D 62/116; H10D 62/154; H10D 62/158

(57) ABSTRACT

The present disclosure describes a semiconductor device having an identification device for chip identification. The semiconductor structure includes first and second channel structures on a substrate, a gate structure on the first and second channel structures, an epitaxial structure on the first and second channel structures, and a first source/drain (S/D) contact structure on the first channel structure. The epitaxial structure is at a first side of the gate structure and the first S/D contact structure is at a second side of the gate structure opposite to the first side. The semiconductor structure further includes a second S/D contact structure on the second channel structure. The second S/D contact structure is at the second side of the gate structure.

### CROSS-REFERENCE TO RELATED APPLICATIONS

The present application is a continuation application of U.S. Non-Provisional patent application Ser. No. 18/516,478, filed on Nov. 21, 2023, titled “Semiconductor Device Structure for Chip Identification,” which claims the benefit of U.S. Provisional Patent Appl. No. 63/518,031, titled “Semiconductor Device Structure for Chip Identification,” and filed on Aug. 7, 2023, the disclosures of which are incorporated by reference in their entireties.

### BACKGROUND

The fabrication of integrated circuits involves the formation of semiconductor devices on the surface of silicon wafers. The integrated circuits are located within discrete units identified as chips or dice. Each chip or die contains devices and circuits which constitute a discrete manufactured product. The chips or dice are arranged in a fashion, on the wafer, to provide a maximum number of functional chips or dice for a final manufactured product. Each manufactured product can have an identification label or a barcode imprinted on the chip to identify the chip.

### BRIEF DESCRIPTION OF THE DRAWINGS

Aspects of the present disclosure are best understood from the following detailed description when read with the accompanying figures.

FIG. 1 illustrates a plan view of a semiconductor device having an identification device for chip identification, in accordance with some embodiments.

FIG. 2 illustrates a partial plan view of an identification device for chip identification in a semiconductor device, in accordance with some embodiments.

FIGS. 3A and 3B illustrate partial cross-sectional views of an identification device for chip identification in a semiconductor device, in accordance with some embodiments.

FIGS. 4A-4F illustrates various embodiments of an identification device for chip identification in a semiconductor device, in accordance with some embodiments.

FIG. 5 is a flow diagram of a method for fabricating a semiconductor device having an identification device for chip identification, in accordance with some embodiments.

FIGS. 6-9 illustrate partial plan views of an identification device for chip identification in a semiconductor device at various stages of its fabrication, in accordance with some embodiments.

FIG. 10 is a flow diagram of a method for testing a semiconductor device having an identification device for chip identification, in accordance with some embodiments.

FIG. 11 illustrates example input and output signals for testing a semiconductor device having an identification device for chip identification, in accordance with some embodiments.

Illustrative embodiments will now be described with reference to the accompanying drawings. In the drawings, like reference numerals generally indicate identical, functionally similar, and/or structurally similar elements.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over a second feature in the description that follows may include embodiments in which the first and second features are formed in direct contact, and may also include embodiments in which additional features may be formed between the first and second features, such that the first and second features may not be in direct contact. As used herein, the formation of a first feature on a second feature means the first feature is formed in direct contact with the second feature. In addition, the present disclosure may repeat reference numerals and/or letters in the various examples. This repetition does not in itself dictate a relationship between the various embodiments and/or configurations discussed.

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

It is noted that references in the specification to “one embodiment,” “an embodiment,” “an example embodiment,” “exemplary,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of one skilled in the art to effect such feature, structure or characteristic in connection with other embodiments whether or not explicitly described.

It is to be understood that the phraseology or terminology herein is for the purpose of description and not of limitation, such that the terminology or phraseology of the present specification is to be interpreted by those skilled in relevant art(s) in light of the teachings herein.

In some embodiments, the terms “about” and “substantially” can indicate a value of a given quantity that varies within 20% of the value (e.g., ±1%, ±2%, ±3%, ±4%, ±5%, ±10%, ±20% of the value). These values are merely examples and are not intended to be limiting. The terms “about” and “substantially” can refer to a percentage of the values as interpreted by those skilled in relevant art(s) in light of the teachings herein.

Chip identification is required in order to provide proper identification of chips that are, for example, manufactured using different manufacturing processes in different batches. Chip identification may also be important in order to easily identify chips that may be required for certain applications. A laser chip scribe of an identification label or a barcode on a chip can be employed to provide chip identification information. However, the laser chip scribe can be modified or removed to change chip identification information, which can create security issues for chip identification.

Various embodiments in the present disclosure provide methods of forming an identification device for chip identification in a semiconductor device in an integrated circuit (IC). In some embodiments, the semiconductor device can include a first number of groups of transistors on a substrate. Each group of transistors can include a second number of transistors. For example, the first number can be greater than 20 and the second number can be between 2 and 22. Each transistor can include a channel structure doped with a dopant. Channel structures in a group of transistors can have different dopant concentration levels and thus different conductivity. The semiconductor device can include one gate structure and one source/drain (S/D) epitaxial structure on each channel structure of the transistors. Each transistor can include a S/D contact structure on its channel structure. The S/D contact structure and the S/D epitaxial structure can be at opposite sides of the gate structure.

With one S/D epitaxial structure, one gate structure, and respective S/D contact structure on each channel structure of the transistors, an input signal to the S/D epitaxial structure of the semiconductor device can reach the S/D contact structure of each transistor at different times, based on the conductivity of the channel structure in each transistor. Accordingly, by comparing the unique output signal of each transistor in one group of transistors, the comparison result can represent one digit for chip identification of the semiconductor device. Collectively, all groups of transistors can represent all the digits of a chip identification number for the semiconductor device. Having an identification device for chip identification instead of a laser chip scribe, the chip identification information of the semiconductor device may not be duplicated or modified. As a result, the security level of the chip identification information of the semiconductor device can be improved.

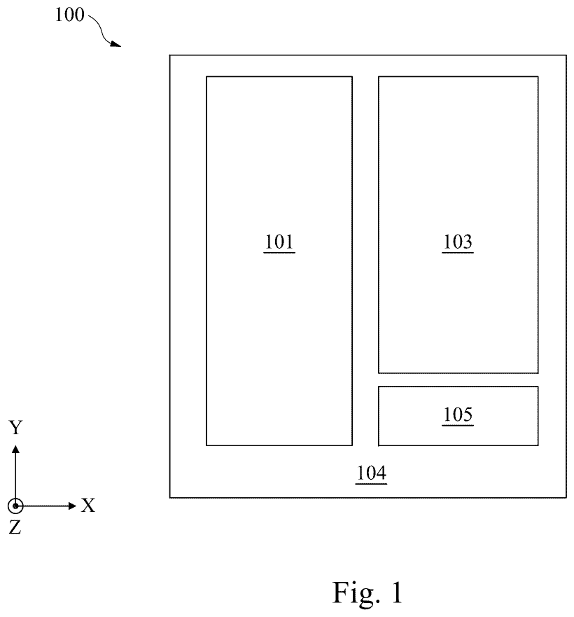

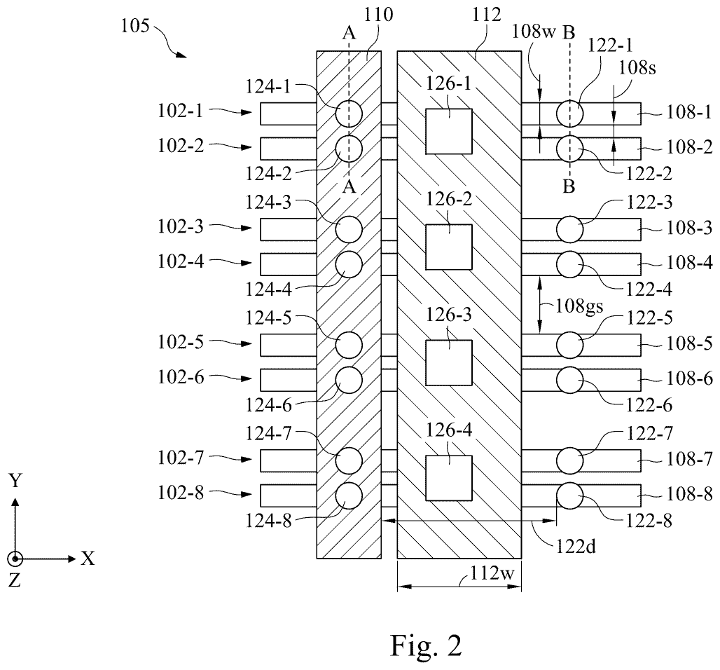

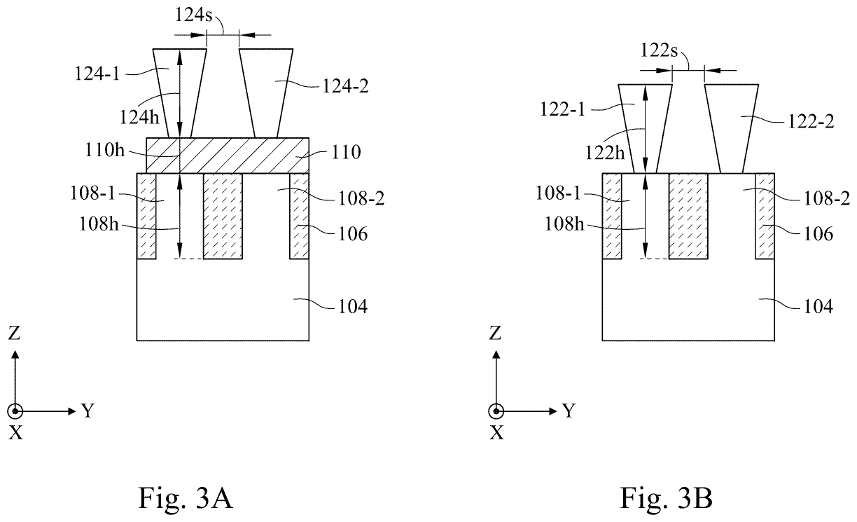

FIG. 1 illustrates a plan view of semiconductor device 100 having an identification device for chip identification, in accordance with some embodiments. FIG. 2 illustrates a partial plan view of an identification device for chip identification in semiconductor device 100, in accordance with some embodiments. FIGS. 3A and 3B illustrate partial cross-sectional views of an identification device for chip identification in semiconductor device 100 along lines A-A and B-B in FIG. 2, in accordance with some embodiments.

In some embodiments, semiconductor device 100 can include a memory device 101, a logic device 103, and an identification device 105, as shown in FIG. 1. In some embodiments, though FIG. 1 shows one memory device 101, one logic device 103, and one identification device 105, semiconductor device 100 can have any number of memory devices 101, any number of logic devices 103, and any number of identification devices 105. In some embodiments, identification device 105 can be located at one location of semiconductor device 100 for chip identification, as shown in FIG. 1. In some embodiments, identification device 105 can have multiple portions located at multiple locations of semiconductor device 100 for chip identification.

In some embodiments, identification device 105 can include transistors 102-1 to 102-8 (collectively referred to as “transistors 102”), as shown in FIG. 2. In some embodiments, transistors 102 can include field effect transistors (FETs), such as planar metal-oxide-semiconductor FETs (MOSFETs) and nanostructure transistors. The nanostructure transistors can include fin field effect transistors (finFETs), gate-all-around field effect transistors (GAA FETs), nanosheet transistors, nanowire transistors, multi-bridge channel transistors, nano-ribbon transistors, and other similar structured transistors. In some embodiments, the nanostructure transistors can provide a channel in a stacked nanoshect/nanowire configuration.

In some embodiments, transistors 102 can be n-type field-effect transistors (NFETs). In some embodiments, transistors 102 can be p-type field-effect transistors (PFETs). Though FIG. 2 shows eight transistors, semiconductor device 100 can have any number of transistors. In addition, semiconductor device 100 can be incorporated into an IC through the use of other structural components, such as conductive vias, conductive lines, dielectric layers, passivation layers, and interconnects, which are not shown for simplicity. The discussion of elements of transistors 102 with the same annotations applies to each other, unless mentioned otherwise. And like reference numerals generally indicate identical, functionally similar, and/or structurally similar elements.

Referring to FIGS. 2 and 3A-3B, identification device 105 can include four groups of transistors 102. In some embodiments, identification device 105 can include more groups of transistors 102. Four groups of transistors 102 are shown in FIG. 2 for case of illustration and explanation purposes. Each group can include two transistors 102. Transistors 102 can include channel structures 108-1 to 108-8 (collectively referred to as “channel structures 108”). Channel structures 108 can be formed on a substrate 104 and can be isolated by shallow trench isolation (STI) regions 106. Identification device 105 can further include S/D epitaxial structure 110, gate structure 112, S/D contact structures 122-1 to 122-8 (collectively referred to as “S/D contact structures 122”), S/D contact structures 124-1 to 124-8 (collectively referred to as “S/D contact structures 124”), and gate contact structures 126-1 to 126-4 (collectively referred to as “gate contact structures 126”). In some embodiments, identification device 105 can further include gate dielectric layers, gate spacers, etch stop layers, interlayer dielectric layers, and other layers and structures, which are not shown for clarity.

Referring to FIGS. 2 and 3A-3B, substrate 104 can include a semiconductor material, such as silicon. In some embodiments, substrate 104 includes a crystalline silicon substrate (e.g., wafer). In some embodiments, substrate 104 includes (i) an elementary semiconductor, such as germanium; (ii) a compound semiconductor including silicon carbide, gallium arsenide, gallium phosphide, indium phosphide, indium arsenide, and/or indium antimonide; (iii) an alloy semiconductor including silicon germanium carbide, silicon germanium, gallium arsenic phosphide, and/or aluminum gallium arsenide; or (iv) a combination thereof. Further, substrate 104 can be doped depending on design requirements (e.g., p-type substrate or n-type substrate). In some embodiments, substrate 104 can be doped with p-type dopants (e.g., boron, indium, aluminum, or gallium) or n-type dopants (e.g., phosphorus or arsenic).

STI regions 106 can provide electrical isolation between transistors 102 and from neighboring transistors (not shown) on substrate 104 and/or neighboring active and passive elements (not shown) integrated with or deposited on substrate 104. STI regions 106 can be made of a dielectric material. In some embodiments, STI regions 106 can include silicon oxide, silicon nitride, silicon oxynitride, fluorine-doped silicate glass (FSG), a low-k dielectric material, and/or other suitable insulating materials. In some embodiments, STI regions 106 can include a multi-layered structure.

Referring to FIGS. 2 and 3A-3B, channel structures 108 can include fin structures formed on patterned portions of substrate 104. Embodiments of the fin structures disclosed herein may be patterned by any suitable method. For example, the fin structures may be patterned using one or more photolithography processes, including double-patterning or multi-patterning processes. Double-patterning or multi-patterning processes can combine photolithography and self-aligned processes, forming patterns that have, for example, pitches smaller than what is otherwise obtainable using a single, direct photolithography process. For example, a sacrificial layer is formed over a substrate and patterned using a photolithography process. Spacers can be formed alongside the patterned sacrificial layer using a self-aligned process. The sacrificial layer is then removed, and the remaining spacers can then be used to pattern the fin structures.

As shown in FIGS. 2 and 3A-3B, channel structures 108 can extend along an X-axis for transistors 102. In some embodiments, channel structures 108 can be disposed on substrate 104. Each of channel structures 108 can act as a channel of transistors 102 and form a channel region underlying gate structure 112 of transistors 102. In some embodiments, channel structures 108 can include semiconductor materials similar to or different from substrate 104. In some embodiments, channel structures 108 can include silicon. In some embodiments, channel structures 108 can include silicon germanium. The semiconductor materials of channel structures 108 can be undoped or can be in-situ doped during their formation process. In some embodiments, as shown in FIG. 2, channel structures 108 under gate structure 112 can form channel regions of identification device 105 and represent current carrying channels of identification device 105.

In some embodiments, channel structures 108 can have a height 108h along a Z-axis ranging from about 50 nm to about 150 nm. In some embodiments, a spacing 108s between adjacent channel structures 108 along a Y-axis can range from about 5 nm to about 15 nm. In some embodiments, a spacing 108gs between adjacent groups of channel structures 108 along a Y-axis can range from about 10 nm to about 50 nm. In some embodiments, spacing 108gs can be greater than spacing 108s. In some embodiments, channel structures 108 can have a width 108w along a Y-axis ranging from about 5 nm to about 15 nm. In some embodiments, adjacent channel structures can have small width variations (e.g., about 3% to about 8%) due to random process variations. For example, width 108w of channel structure 108-1 can be about 10.5 nm while width 108w of channel structure 108-2 can be about 10.1 nm.

In some embodiments, channel structures 108 can be doped with an implant process followed by a thermal anneal. In some embodiments, transistors 102 can include NFETs and channel structures 108 can include phosphorous, nitrogen, arsenic, or other n-type dopants. In some embodiments, a concentration of the n-type dopant in channel structures 108 can range from about be about 1×10¹⁹ atoms/cm⁻³ to about 1×10²² atoms/cm⁻³. In some embodiments, transistors 102 can include PFETs and channel structures 108 can include boron, gallium, or other p-type dopants. In some embodiments, a concentration of the p-type dopant in channel structures 108 can range from about be about 1×10¹⁹ atoms/cm⁻³ to about 5×10²¹ atoms/cm⁻³.

In some embodiments, the dopant concentration in each channel structure of a group of transistors can be different. For example, the dopant concentration in channel structure 108-1 can be different from the dopant concentration in channel structure 108-2. In some embodiments, due to a block of dopant diffusion by wider channel structures, channel structures 108 having a greater width than other channel structures 108 in one group of transistors 102 can have a lower dopant concentration. For example, if width 108w of channel structure 108-1 is greater than width 108w of channel structure 108-2, the dopant concentration in channel structure 108-1 can be less than the dopant concentration in channel structure 108-2. With a higher dopant concentration, channel structure 108-2 can have a higher conductivity and signals can travel faster through transistor 102-2. Accordingly, the dopant concentration difference in channel structures 108 can act as fingerprints of semiconductor device 100 for identification, which can be illustrated by the signal speed through transistors 102.

In some embodiments, as shown in FIG. 2, gate structure 112 can be disposed on channel structures 108. In some embodiments, identification device 105 can include one gate structure 112 disposed on each channel structure 108 to simultaneously control each transistor 102. In some embodiments, gate structure 112 can include a gate dielectric layer, one or more work function metal layers, and a metal fill. In some embodiments, the gate dielectric layer can be multi-layered structures and can include an interfacial layer and a high-k dielectric layer. In some embodiments, the gate dielectric layer can include no interfacial layer and a high-k dielectric layer in direct contact with channel structures 108. In some embodiments, the interfacial layer can include silicon oxide formed by a deposition process or an oxidation process. In some embodiments, the high-k dielectric layer can include hafnium oxide, zirconium oxide, or other suitable high-k dielectric materials. In some embodiments, gate structure 112 can have a width 112w along an X-axis ranging from about 5 nm to about 20 nm.

In some embodiments, the one or more work function metal layers can include work function metals to tune the threshold voltage (Vₜ) of transistors 102. In some embodiments, gate structure 112 for NFET devices can include n-type work-function metal layers. The n-type work function metal layers can include aluminum, titanium aluminum, titanium aluminum carbon, tantalum aluminum, tantalum aluminum carbon, tantalum silicon carbide, hafnium carbide, silicon, titanium nitride, titanium silicon nitride, or other suitable work function metals. In some embodiments, gate structure 112 for PFET devices can include p-type work-function metal layers. The p-type work function metal layers can include titanium nitride, titanium silicon nitride, tantalum nitride, tungsten carbon nitride, tungsten, molybdenum, or other suitable work function metals. In some embodiments, the work function metal layers can include a single metal layer or a stack of metal layers. The stack of metal layers can include work function metals having work-function values equal to or different from each other. In some embodiments, transistors 102 can include any number of work function metal layers for Vₜ tuning (e.g., ultra-low Vₜ, low Vₜ, and standard Vₜ). In some embodiments, the metal fill can include titanium, tantalum, aluminum, cobalt, tungsten, nickel, ruthenium, or other suitable conductive materials.

In some embodiments, identification device 105 can include gate spacers (not shown) disposed on sidewalls of gate structure 112. The gate spacers can include insulating materials, such as silicon oxide, silicon nitride, silicon oxynitride, silicon carbonitride, silicon oxycarbide, silicon oxycarbonitride, a low-k material, and a combination thereof. The gate spacers can include a single layer or a stack of insulating layers. In some embodiments, the gate spacers can have a low-k material with a dielectric constant less than about 3.9 (e.g., about 3.5, about 3.0, or about 2.8).

Referring to FIG. 2, gate contact structures 126 can be disposed on gate structure 112. In some embodiments, each gate contact structure 126 can be disposed over one group of channel structures 108. For example, as shown in FIG. 2, gate contact structure 126-1 can be disposed over channel structures 108-1 and 108-2, gate contact structure 126-2 can be disposed over channel structures 108-3 and 108-4, gate contact structure 126-3 can be disposed over channel structures 108-5 and 108-6, and gate contact structure 126-4 can be disposed over channel structures 108-7 and 108-8. In some embodiments, gate contact structures 126 can include conductive materials, such as tungsten, aluminum, and cobalt.

In some embodiments, as shown in FIG. 2, S/D epitaxial structure 110 can be disposed on channel structures 108 at a first side (e.g., left side) of gate structure 112. S/D epitaxial structure 110 can function as S/D regions of transistors 102. In some embodiments, identification device 105 can include one merged S/D epitaxial structure 110 disposed on each channel structure 108 for simultaneous signal input to each transistor 102. In some embodiments, S/D epitaxial structure 110 can have any geometric shape, such as a polygon, an ellipsis, and a circle. In some embodiments, S/D epitaxial structure 110 can include an epitaxially-grown semiconductor material, such as silicon (e.g., the same material as substrate 104). In some embodiments, the epitaxially-grown semiconductor material can include an epitaxially-grown semiconductor material different from the material of substrate 104, such as silicon germanium, and imparts a strain on the channel regions under gate structure 112. Since the lattice constant of such epitaxially-grown semiconductor material is different from the material of substrate 104, the channel regions are strained to increase carrier mobility in the channel regions of identification device 105. The epitaxially-grown semiconductor material can include: (i) a semiconductor material, such as germanium and silicon; (ii) a compound semiconductor material, such as gallium arsenide and aluminum gallium arsenide; or (iii) a semiconductor alloy, such as silicon germanium and gallium arsenide phosphide.

In some embodiments, S/D epitaxial structure 110 can include silicon and can be in-situ doped during an epitaxial growth process using n-type dopants, such as phosphorus and arsenic. In some embodiments, S/D epitaxial structure 110 can include silicon, silicon germanium, germanium, or III-V materials (e.g., indium antimonide, gallium antimonide, or indium gallium antimonide) and can be in-situ doped during an epitaxial growth process using p-type dopants, such as boron, indium, and gallium. In some embodiments, S/D epitaxial structure 110 can include one or more epitaxial layers, where each epitaxial layer can have different compositions. In some embodiments, S/D epitaxial structure 110 can have a thickness along a Z-axis ranging from about 10 nm to about 100 nm.

In some embodiments, as shown in FIG. 3A, S/D contact structures 124 can be disposed on S/D epitaxial structure 110 over channel structures 108. In some embodiments, S/D contact structures 124 can include a metal contact formed on S/D epitaxial structure 110. In some embodiments, S/D contact structures 124 can include a silicide layer and a metal contact. In some embodiments, the silicide layer can include metal silicide and can provide a lower resistance interface between the metal contact and S/D epitaxial structure 110. Examples of metal used for forming the metal silicide include cobalt, titanium, and nickel. In some embodiments, the metal contact can include conductive materials, such as tungsten, aluminum, and cobalt.

In some embodiments, as shown in FIG. 3A, S/D contact structures 124 can have a height 124h along a Z-axis ranging from about 10 nm to about 50 nm. In some embodiments, a spacing 124s between adjacent S/D contact structures 124 can range from about 5 nm to about 15 nm. In some embodiments, a ratio of height 124h of S/D contact structures 124 to height 108h of channel structures 108 can range from about 0.25 to about 0.5. If the ratio is less than about 0.25, S/D contact structures 124 may not have good contact with S/D epitaxial structure 110. If the ratio is greater than about 0.5, adjacent S/D contact structures 124 may short and manufacturing cost may increase. In some embodiments, S/D contact structures 124 can have a conical shape with a top diameter greater than a bottom diameter. In some embodiments, a ratio of the top diameter to the bottom diameter can range from about 1.1 to about 1.3.

In some embodiments, as shown in FIGS. 2 and 3B, S/D contact structures 122 can be disposed directly on channel structures 108 at a second side (e.g., right side) of gate structure 112 opposite to the first side. In some embodiments, S/D contact structures 122 can be separated from each other and each of channel structures 108 can have at least one S/D contact structure 122. In some embodiments, similar to S/D contact structures 124, S/D contact structures 122 can include a metal contact formed on channel structures 108. In some embodiments, similar to S/D contact structures 124, S/D contact structures 122 can include a silicide layer and a metal contact. In some embodiments, the silicide layer can include metal silicide and can provide a lower resistance interface between the metal contact and channel structures 108. Examples of metal used for forming the metal silicide include cobalt, titanium, and nickel. In some embodiments, the metal contact can include conductive materials, such as tungsten, aluminum, and cobalt.

In some embodiments, an interlayer dielectric (ILD) layer (not shown) can be disposed among gate contact structures 126 and S/D contact structures 122 and 124 for isolation. In some embodiments, the ILD layer can include a dielectric material deposited using a deposition method suitable for flowable dielectric materials. For example, flowable silicon oxide can be deposited using flowable chemical vapor deposition (FCVD). In some embodiments, the dielectric material can include silicon oxide.

In some embodiments, as shown in FIG. 3B, S/D contact structures 122 can have a height 122h along a Z-axis ranging from about 10 nm to about 50 nm. In some embodiments, a spacing 122s between adjacent S/D contact structures 122 can range from about 5 nm to about 15 nm. In some embodiments, a ratio of height 122h of S/D contact structures 122 to height 108h of channel structures 108 can range from about 0.25 to about 0.5. If the ratio is less than about 0.25, S/D contact structures 124 may not have good contact with channel structures 108. If the ratio is greater than about 0.5, adjacent S/D contact structures 122 may short and manufacturing cost may increase. In some embodiments, similar to S/D contact structures 124, S/D contact structures 122 can have a conical shape with a top diameter greater than a bottom diameter. In some embodiments, a ratio of the top diameter to the bottom diameter can range from about 1.1 to about 1.3. In some embodiments, a distance 122d between S/D contact structures 122 and S/D contact structures 124 can range from about 5 nm to about 50 nm. A ratio of distance 122d to width 112w of gate structure 112 can range from about 1 to about 3. If the ratio is less than about 1 or distance 122d is less than about 5 nm, it may be difficult to compare the signal speed in different channel structures 108. If the ratios is greater than about 3, or distance 122d is greater than about 50 nm, identification device 105 may consume additional chip area.

In some embodiments, as shown in FIG. 2, with one S/D epitaxial structure 110 connected to channel structures 108 at the first side of transistors 102, an input signal can be inputted to each of transistors 102 via S/D epitaxial structure 110 at the same time. With one gate structure 112 on channel structures 108, transistors 102 can be turned on at the same time. Adjacent channel structures 108 in a group of channel structures 108 (e.g., channel structures 108-1 and 108-2) can have different dopant concentrations due to random channel structure width variations. Different dopant concentrations can lead to different conductivities of channel structures 108. As a result, the input signal at the first side of transistors 102 can be measured at different times on S/D contact structures 122 at the second side of transistors 102.

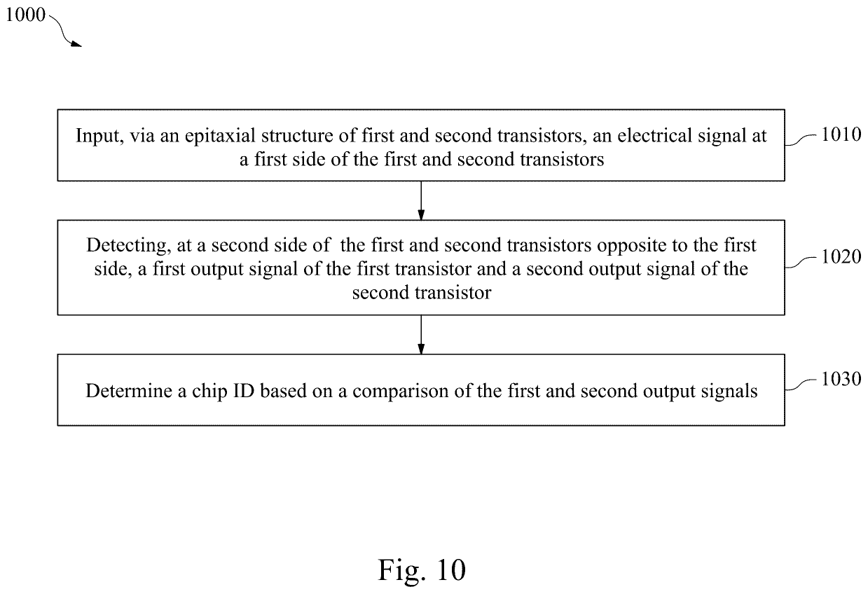

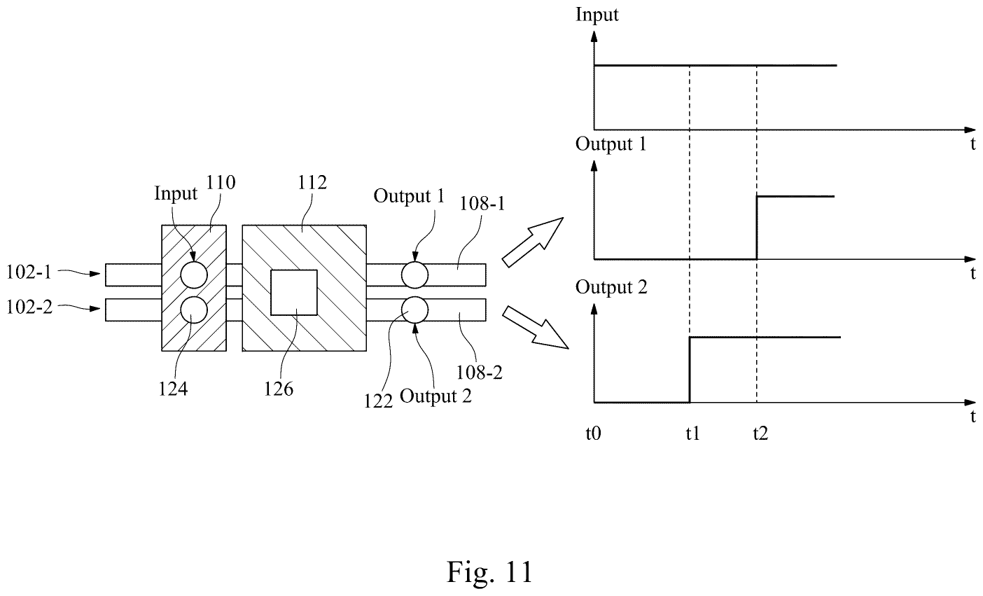

Accordingly, by comparing the unique output signal of each transistor 102 in one group of transistors (e.g., on S/D contact structures 122-1 and 122-2), the comparison result can represent one digit for chip identification. For example, if the output signal reaches S/D contact structure 122-1 before S/D contact structure 122-2, the first binary digit for chip identification can be “0.” If the output signal reaches S/D contact structure 122-2 before S/D contact structure 122-1, the first binary digit for chip identification can be “1.” Similarly, additional digits of the chip identification for semiconductor device 100 can be determined based on comparison results of the transistors in each of the other groups of transistors. Collectively, all groups of transistors 102 can uniquely determine the digits of a chip identification number for semiconductor device 100. The testing process and input/output signals are described in detail in FIGS. 10 and 11. With identification device 105 for chip identification instead of a laser chip scribe, the chip identification information of semiconductor device 100 may not be duplicated or modified. As a result, the security level of the chip identification information of semiconductor device 100 can be improved.

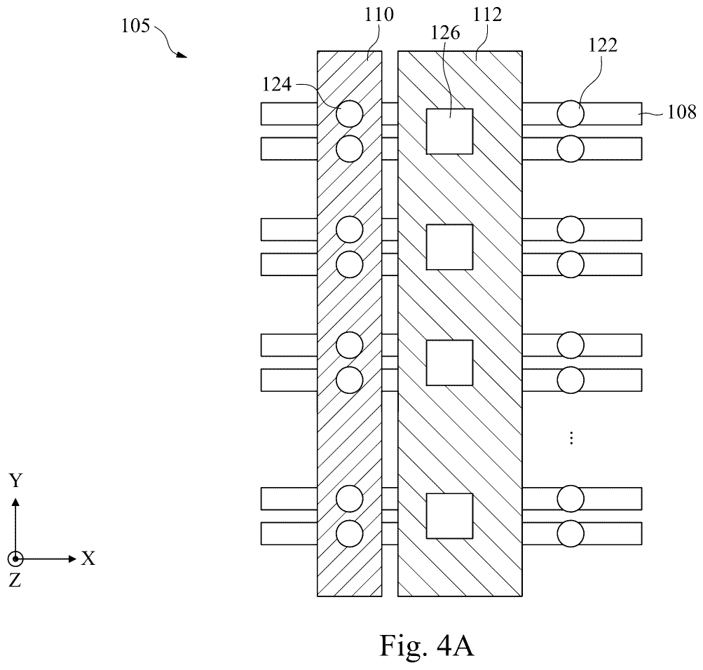

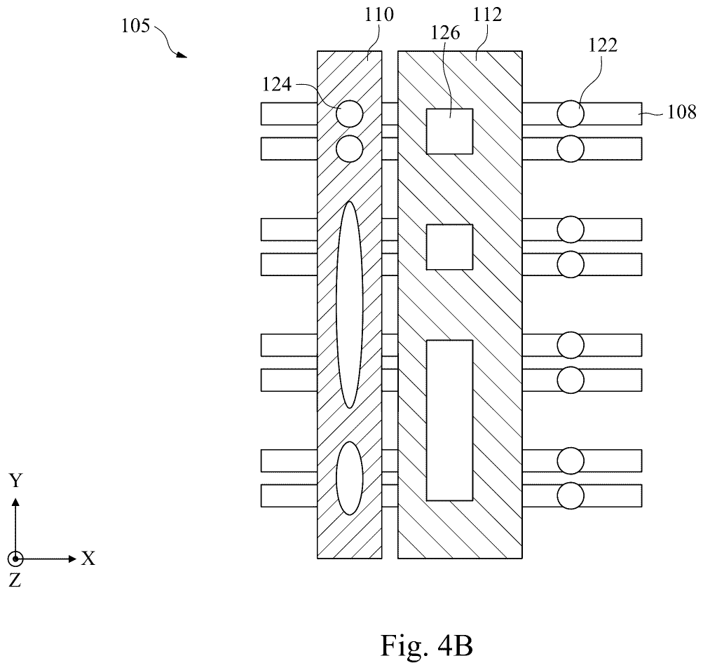

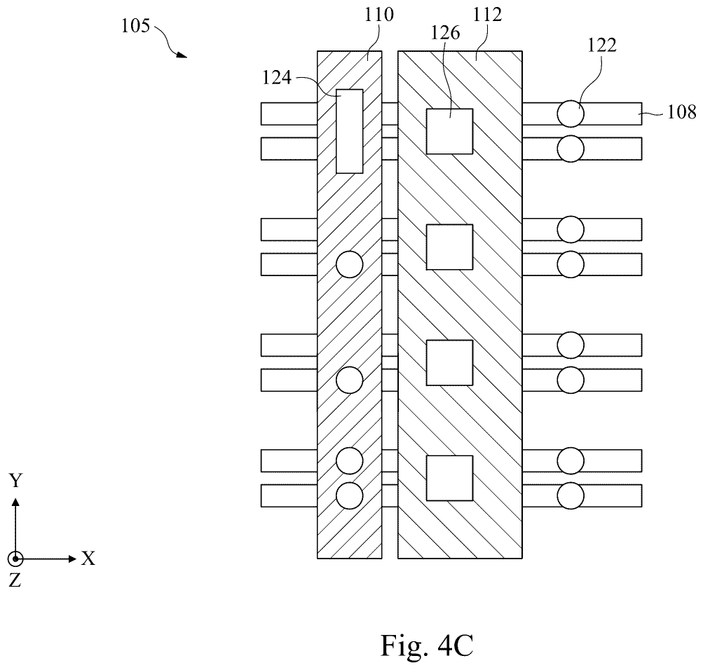

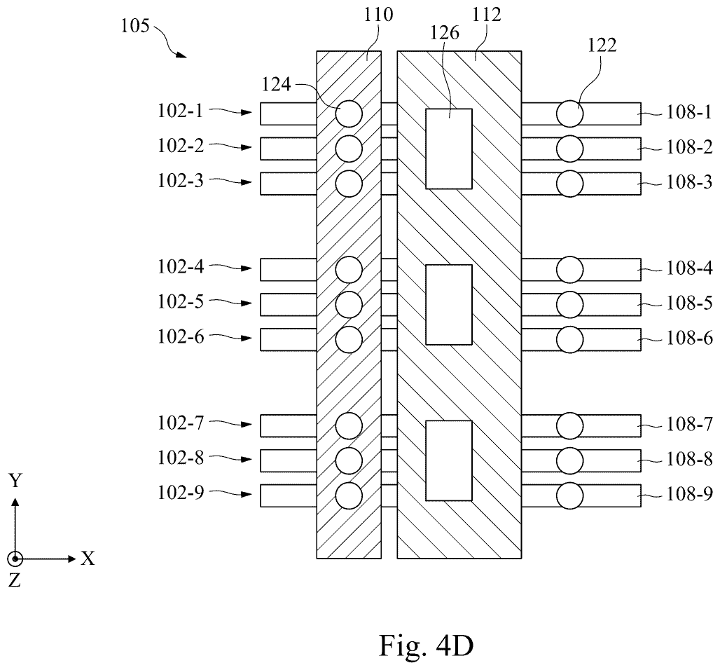

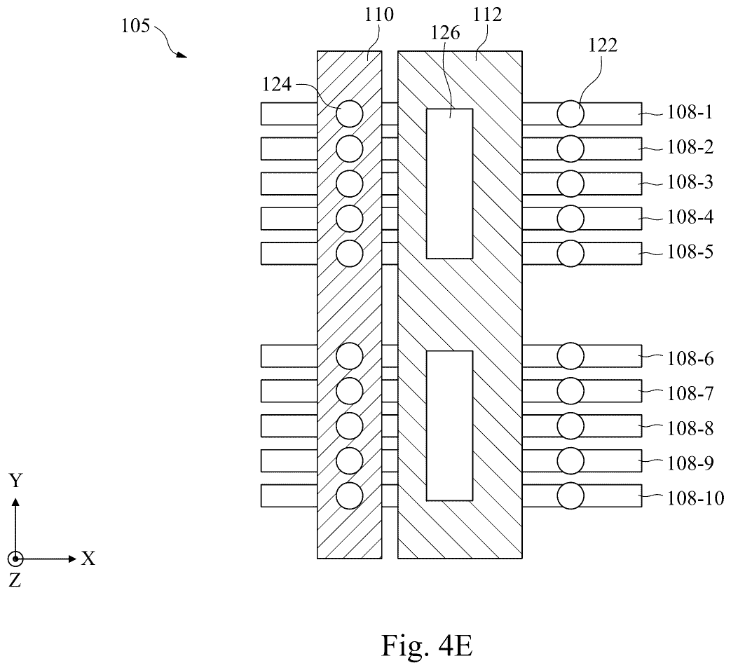

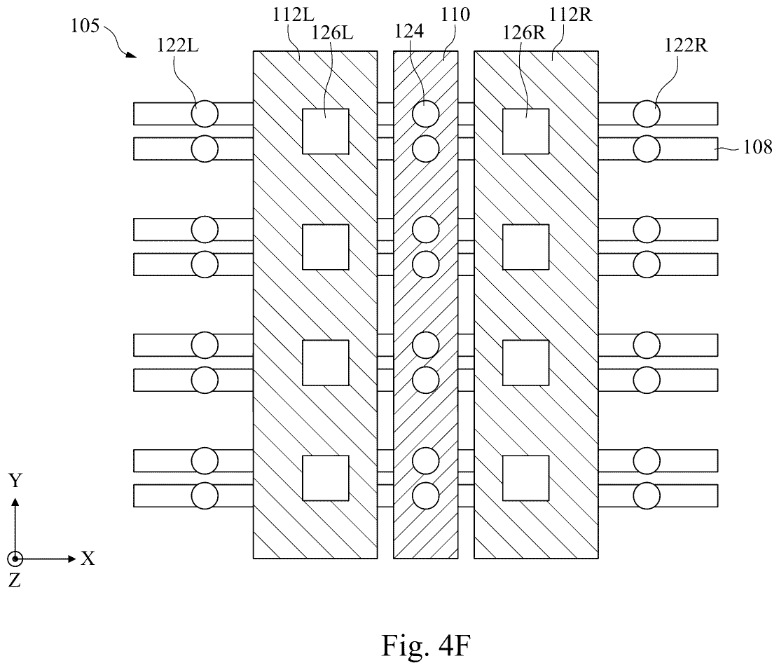

In some embodiments, identification device 105 can have more groups of channel structures, as shown in FIG. 4A. In some embodiments, the number of groups of channel structures 108 can be greater than about 20. If the number of groups is less than about 20, identification device 105 may not have enough digits for chip identification of semiconductor device 100. In some embodiments, as shown in FIGS. 4B and 4C, S/D contact structures 124 and gate contact structures 126 can have any geometric shape, such as a polygon, an ellipsis, and a circle. Additionally, S/D contact structures 124 and gate contact structures 126 can extend over two or more channel structures 108 as shown in FIG. 2, as S/D epitaxial structure 110 is merged together and connected to each of channel structures 108. Additionally, S/D contact structures 124 may not be disposed directly above some channel structures 108. In some embodiments, the number of channel structures 108 in each group can be greater than 2, for example, 3 and 5 as shown in FIGS. 4D and 4E. In some embodiments, channel structures 108 in each group can have equal spacings. In some embodiments, the number of channel structures 108 in each group can range from 2 to 22. A larger number of channel structures 108 in each group can represent additional digits for chip identification of semiconductor device 100. In some embodiments, identification device 105 can have a mirror structure as shown in FIG. 4F to reduce chip area of identification device 105. As shown in FIG. 4F, identification device 105 can include one S/D epitaxial structure 110 and two gate structures 112L and 112R disposed at opposite sides of S/D epitaxial structure 110. Identification device 105 can further include gate contact structures 126L disposed on gate structure 112L and gate contact structures 126R disposed on gate structure 112R. S/D contact structures 122L and 122R can be disposed on channel structures 108 at opposite sides of gate structures 112L and 112R.

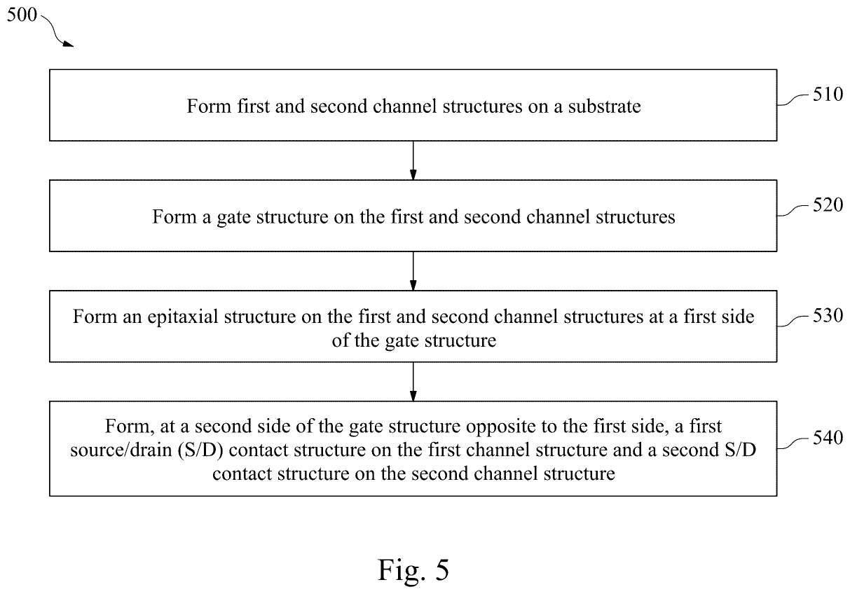

FIG. 5 is a flow diagram of a method 500 for fabricating semiconductor device 100 having an identification device for chip identification, in accordance with some embodiments. Method 500 may not be limited to semiconductor device 100 for chip identification and can be applicable to other devices that would benefit from the identification device. Additional fabrication operations may be performed between various operations of method 500 and may be omitted merely for clarity and case of description. Additional processes can be provided before, during, and/or after method 500; one or more of these additional processes are briefly described herein. Moreover, not all operations may be needed to perform the disclosure provided herein. Additionally, some of the operations may be performed simultaneously or in a different order than shown in FIG. 5. In some embodiments, one or more other operations may be performed in addition to or in place of the presently-described operations.

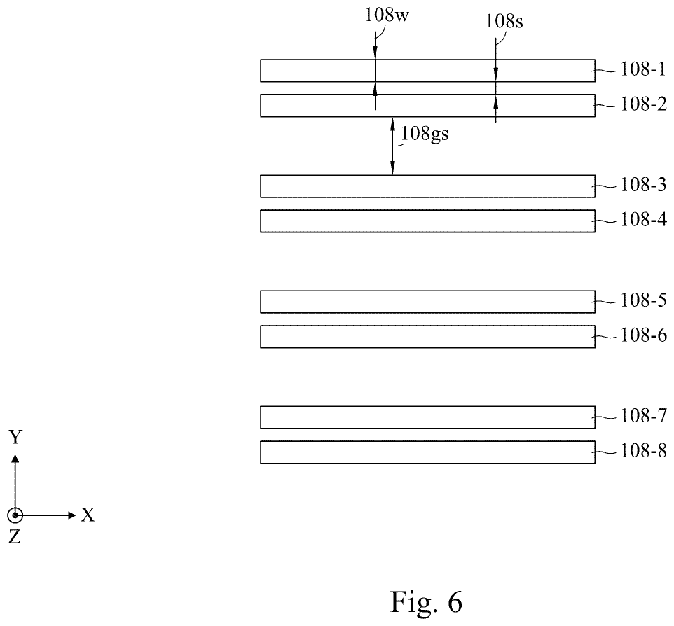

For illustrative purposes, the operations illustrated in FIG. 5 will be described with reference to the example fabrication process for fabricating semiconductor device 100 as illustrated in FIGS. 6-9. FIGS. 6-9 illustrate partial plan views of an identification device for chip identification in semiconductor device 100 at various stages of its fabrication, in accordance with some embodiments. Elements in FIGS. 6-9 with the same annotations as elements in FIGS. 2 and 3A-3B are described above.

In referring to FIG. 5, method 500 begins with operation 510 and the process of forming first and second channel structures on a substrate. For example, as shown in FIG. 6, four groups of channel structures 108-1 to 108-8 can be formed on substrate 104. In some embodiments, semiconductor device 100 can include more groups of channel structures 108 and four groups of channel structures 108 are shown in FIGS. 6-9 for case of illustration and explanation purposes. Embodiments of channel structures 108 may be patterned by any suitable method. For example, channel structures 108 may be patterned using one or more photolithography processes, including double-patterning or multi-patterning processes. Double-patterning or multi-patterning processes can combine photolithography and self-aligned processes, forming patterns that have, for example, pitches smaller than what is otherwise obtainable using a single, direct photolithography process. For example, a sacrificial layer is formed over a substrate and patterned using a photolithography process. Spacers can be formed alongside the patterned sacrificial layer using a self-aligned process. The sacrificial layer is then removed, and the remaining spacers can then be used to pattern channel structures 108.

In some embodiments, a spacing 108s between adjacent channel structures 108 along a Y-axis can range from about 5 nm to about 15 nm. In some embodiments, a spacing 108gs between adjacent groups of channel structures 108 along a Y-axis can range from about 10 nm to about 50 nm. In some embodiments, spacing 108gs can be greater than spacing 108s. In some embodiments, channel structures 108 can have a width 108w along a Y-axis ranging from about 5 nm to about 15 nm. In some embodiments, adjacent channel structures can have small width variations (e.g., about 3% to about 8%) due to random process variations. For example, width 108w of channel structure 108-1 can be about 10.5 nm while width 108w of channel structure 108-2 can be about 10.1 nm.

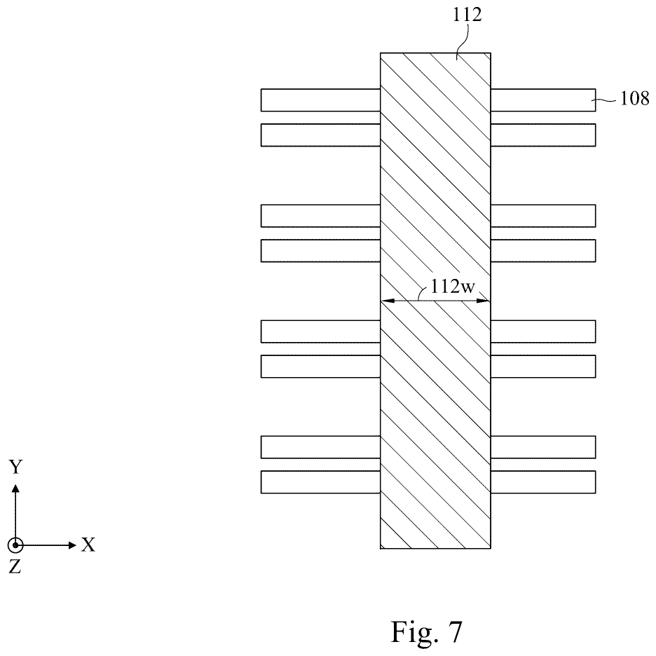

Referring to FIG. 5, method 500 continues with operation 520 and the process of forming a gate structure on the first and second channel structures. For example, as shown in FIG. 7, gate structure 112 can be formed on channel structures 108. In some embodiments, gate structure 112 can include a gate dielectric layer, one or more work function metal layers, and a metal fill, which are sequentially deposited and patterned to form gate structure 112. In some embodiments, gate structure 112 can be formed on each of channel structures 108 to simultaneously control each of channel structures 108. In some embodiments, gate structure 112 can have a width 112w along an X-axis ranging from about 5 nm to about 20 nm.

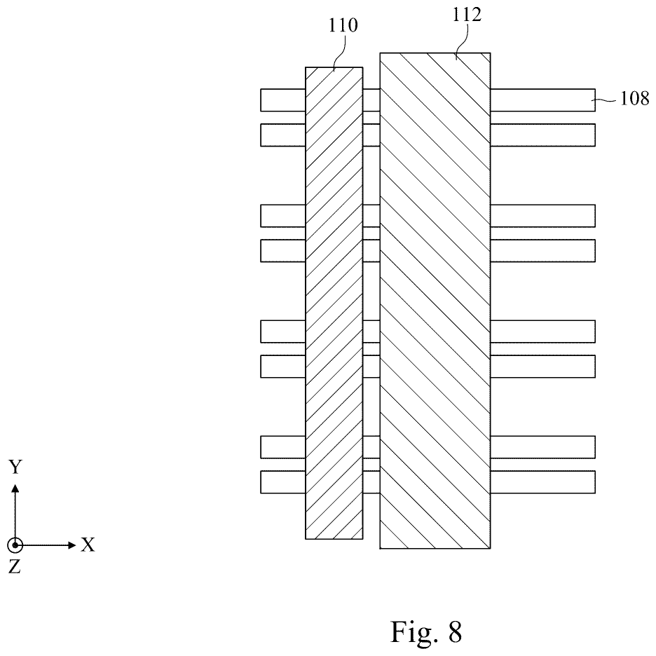

Referring to FIG. 5, in operation 530, an epitaxial structure is formed on the first and second channel structures at a first side of the gate structure. For example, as shown in FIG. 8, S/D epitaxial structure 110 can be formed on channel structures 108 at a first side (e.g., left side) of gate structure 112. In some embodiments, S/D epitaxial structure 110 can be epitaxially grown on channel structures 108 and can be merged into one S/D epitaxial structure 110. In some embodiments, S/D epitaxial structure 110 can be epitaxially grown by (i) chemical vapor deposition (CVD), such as low pressure CVD (LPCVD), atomic layer CVD (ALCVD), ultrahigh vacuum CVD (UHVCVD), reduced pressure CVD (RPCVD), and other suitable CVD processes; (ii) molecular beam epitaxy (MBE) processes; (iii) any suitable epitaxial process; or (iv) a combination thereof. In some embodiments, S/D epitaxial structure 110 can be grown by an epitaxial deposition/partial etch process, which can repeat the epitaxial deposition/partial etch process multiple times. Such repeated deposition/partial etch process can be referred to as a cyclic deposition-etch (CDE) process. The CDE process can reduce epitaxial defects formed during the growth and can control the profiles of S/D epitaxial structure 110. In some embodiments, S/D epitaxial structure 110 can be in-situ doped with n-type or p-type dopants during the epitaxial growth process.

In some embodiments, S/D epitaxial structure 110 can include silicon and can be in-situ doped during an epitaxial growth process using n-type dopants, such as phosphorus and arsenic. In some embodiments, S/D epitaxial structure 110 can include silicon, silicon germanium, germanium, or III-V materials (e.g., indium antimonide, or indium gallium antimonide) and can be in-situ doped during an epitaxial growth process using p-type dopants, such as boron, indium, and gallium. In some embodiments, S/D epitaxial structure 110 can include one or more epitaxial layers, where each epitaxial layer can have different compositions.

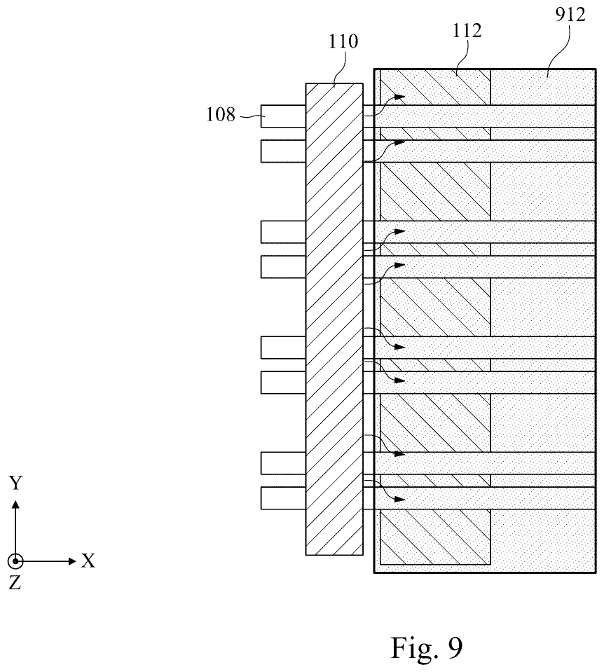

In some embodiments, the formation of S/D epitaxial structure 110 can be followed by an implant process, as shown in FIG. 9. Referring to FIG. 9, a hard mask layer 912 can be formed and patterned to cover gate structure 112 and channel structures 108 at the second side (e.g., right side) of gate structure 112. In some embodiments, the implant process can dope S/D epitaxial structure 110 and channel structures 108 at the first side with a dopant. In some embodiments, the dose of implanted dopant can range from about 1×10¹² cm⁻² to about 1×10¹⁸ cm⁻². The implant process can be performed at a temperature ranging from about 20° C. to about 100° C. In some embodiments, the implanted dopant can include phosphorus, nitrogen, boron, and/or arsenic. In some embodiments, the implanted dopant can include n-type dopants (e.g., phosphorus or arsenic) for NFET transistors 102. In some embodiments, the implanted dopant can include p-type dopants (e.g., boron, indium, aluminum, or gallium) for PFET transistors 102.

In some embodiments, the implant process to dope S/D epitaxial structure 110 and channel structures 108 with the dopant can be followed by a thermal anneal. In some embodiments, the anneal process can be performed at a temperature ranging from about 800° C. to about 1000° C. for a time period ranging from about 30 min to about 60 min. In some embodiments, the anneal process can drive the implanted dopant to diffuse along channel structures 108 toward the second side (e.g., right side) of gate structure 112. In some embodiments, adjacent channel structures can have small width variations (e.g., about 3% to about 8%) due to random process variations. Wider channel structures 108 can have more dopant diffusion block and thus lower dopant concentration after the anneal process. For example, if width 108w of channel structure 108-1 is greater than width 108w of channel structure 108-2, the dopant concentration in channel structure 108-1 can be less than the dopant concentration in channel structure 108-2.

Referring to FIG. 5, in operation 540, at a second side of the gate structure opposite to the first side, a first S/D contact structure is formed on the first channel structure and a second S/D contact structure is formed on the second S/D contact structure. For example, as shown in FIG. 2, at the second side (e.g., right side) of gate structure 112, S/D contact structures 122 can be formed on each of channel structures 108. In some embodiments, S/D contact structures 122 can be separated from each other and each of channel structures 108 can have at least one S/D contact structure 122. In some embodiments, S/D contact structures 122 can include a metal contact. In some embodiments, S/D contact structures 122 can include a silicide layer and a metal contact. In some embodiments, the silicide layer can include metal silicide and can provide a lower resistance interface between the metal contact and channel structures 108. Examples of metal used for forming the metal silicide include cobalt, titanium, and nickel. In some embodiments, the metal contact can include conductive materials, such as tungsten, aluminum, and cobalt.

In some embodiments, the formation of S/D contact structures 122 can be followed by the formation of S/D contact structures 124 on S/D epitaxial structure 110 and formation of gate contact structures 126 on gate structure 112. In some embodiments, gate contact structures 126 and S/D contact structures 122 and 124 can be formed in a same formation process. In some embodiments, the formation of gate contact structures 126 and S/D contact structures 122 and 124 can be followed by the formation of metal vias, metal lines, and interlayer dielectrics, which are not described in details for clarity.

FIG. 10 is a flow diagram of a method 1000 for testing semiconductor device 100 having an identification device for chip identification, in accordance with some embodiments. Method 1000 may not be limited to chip identification testing of semiconductor device 100 and can be applicable to other devices that would benefit from the chip identification testing. Additional fabrication operations may be performed between various operations of method 1000 and may be omitted merely for clarity and case of description. Additional processes can be provided before, during, and/or after method 1000; one or more of these additional processes are briefly described herein. Moreover, not all operations may be needed to perform the disclosure provided herein. Additionally, some of the operations may be performed simultaneously or in a different order than shown in FIG. 10. In some embodiments, one or more other operations may be performed in addition to or in place of the presently-described operations.

For illustrative purposes, the operations illustrated in FIG. 10 will be described with reference to the example testing diagram of semiconductor device 100 as illustrated in FIG. 11. FIG. 11 illustrates example input and output signals for testing two transistors in semiconductor device 100 for chip identification, in accordance with some embodiments. Elements in FIG. 11 with the same annotations as elements in FIGS. 2 and 3A-3B are described above.

In referring to FIG. 10, method 1000 begins with operation 1010 and the process of input, via an epitaxial structure of first and second transistors, an electrical signal at a first side of the first and second transistors. For example, as shown in FIG. 11, an input electrical signal can be inputted to transistors 102-1 and 102-2 via S/D epitaxial structure 110 and S/D contact structures 124 at the first side (e.g., left side) of transistors 102-1 and 102-2. In some embodiments, as shown in FIG. 11, the input electrical signal can be a logic high value and can be inputted to transistors 102-1 and 102-2 at time t0. As S/D epitaxial structure 110 is connected to channel structures 108-1 and 108-2, the input electrical signal can be inputted to transistors 102-1 and 102-2 at the same time to.

Referring to FIG. 10, in operation 1020, a first output signal of the first transistor and a second output signal of the second transistor are detected at a second side of the first and second transistors opposite to the first side. For example, as shown in FIG. 11, output electrical signals output 1 of transistor 102-1 and output 2 of transistor 102-2 can be detected via S/D contact structures 122 at the second side (e.g., right side) of transistors 102-1 and 102-2. In some embodiments, as shown in FIG. 11, when channel structure 108-1 is wider than channel structure 108-2 and thus channel structure 108-1 has a lower dopant concentration than channel structure 108-2, channel structure 108-1 can have a lower conductivity and the electrical signal in channel structure 108-1 can travel slower than the electrical signal in channel structure 108-2. As a result, output 1 of transistor 102-1 can detect the output electrical signal at a time t2 and output 2 of transistor 102-2 can detect the output electrical signal at a time t1, where time t1 is earlier than time t2.

Referring to FIG. 10, in operation 1030, a chip ID is determined based on a comparison of the first and second output signals. For example, as shown in FIG. 11, first digit of a chip identification number for semiconductor device 100 can be determined based on a comparison of the first and second output signals output 1 and output 2. For example, as shown in FIG. 11, the output signal output 2 of transistor 2 can be detected at time t1 earlier than the output signal output 1 of transistor 1. Accordingly, the first binary digit of the chip identification number for semiconductor device 100 can be, for example, “1.” The comparison result of first group of transistors 102-1 and 102-2 can determine the first digit of the chip identification number. Similarly, additional digits of the chip identification number for semiconductor device 100 can be determined based on comparison results of the transistors in each of the other groups of transistors 102. Collectively, all groups of transistors 102 can uniquely determine all the digits of the chip identification number for semiconductor device 100. With identification device 105 for chip identification instead of a laser chip scribe, the chip identification number of semiconductor device 100 may not be duplicated or modified. As a result, the security level of the chip identification number of semiconductor device 100 can be improved.

Various embodiments in the present disclosure provide methods of forming identification device 105 for chip identification in semiconductor device 100. In some embodiments, semiconductor device 100 can include a first number of groups of transistors 102 on substrate 104. Each group of transistors 102 can include a second number of transistors 102. For example, the first number can be greater than 20 and the second number can be between 2 and 22. Each transistor 102 can include one channel structure 108 doped with a dopant. Channel structures 108 in a group of transistors 102 can have different dopant concentration levels and thus different conductivity. Semiconductor device 100 can include one gate structure 112 and one S/D epitaxial structure 110 on channel structures 108 of each transistor 102. Each transistor 102 can include one or more S/D contact structures 122 on each channel structures 108 of transistors 102. S/D contact structures 122 and S/D epitaxial structure 110 can be at opposite sides of gate structure 112.

With one S/D epitaxial structure 110, one gate structure 112, and respective S/D contact structure 122 on each channel structure 108 of transistors 102, an input signal to S/D epitaxial structure 110 of semiconductor device 100 can reach S/D contact structure 122 of each transistor at different times, based on the conductivity of channel structure 108 in each transistor 102. Accordingly, by comparing the unique output signal of each transistor 102 in one group of transistors 102, the comparison result can represent one digit of a chip identification number for semiconductor device 100. Collectively, all groups of transistors 102 can represent all the digits for chip identification of semiconductor device 100. Having identification device 105 for chip identification instead of a laser chip scribe, security level of the chip identification information of semiconductor device 100 can be improved.

In some embodiments, a semiconductor structure includes first and second channel structures on a substrate, a gate structure on the first and second channel structures, an epitaxial structure on the first and second channel structures, and a first source/drain (S/D) contact structure on the first channel structure. The epitaxial structure is at a first side of the gate structure and the first S/D contact structure is at a second side of the gate structure opposite to the first side. The semiconductor structure further includes a second S/D contact structure on the second channel structure. The second S/D contact structure is at the second side of the gate structure.

In some embodiments, a semiconductor device includes first and second transistors on a substrate. The first transistor includes a first channel structure on the substrate, a gate structure on the first channel structure, an epitaxial structure on the first channel structure at a first side of the gate structure, and a first source/drain (S/D) contact structure on the first channel structure at a second side of the gate structure opposite to the first side. The second transistor includes a second channel structure on the substrate, the gate structure on the second channel structure, the epitaxial structure on the second channel structure at the first side of the gate structure, and a second source/drain (S/D) contact structure on the second channel structure at the second side of the gate structure. The second S/D contact structure is separate from the first S/D contact structure.

In some embodiments, a method includes forming first and second channel structures on a substrate, forming a gate structure on the first and second channel structures, forming, at a first side of the gate structure, an epitaxial structure on the first and second channel structures, and forming, at a second side of the gate structure opposite to the first side, a first source/drain (S/D) contact structure on the first channel structure and a second S/D contact structure on the second channel structure. The first and second S/D contact structures are separated from each other.

It is to be appreciated that the Detailed Description section, and not the Abstract of the Disclosure section, is intended to be used to interpret the claims. The Abstract of the Disclosure section may set forth one or more but not all possible embodiments of the present disclosure as contemplated by the inventor(s), and thus, are not intended to limit the subjoined claims in any way.

The foregoing disclosure outlines features of several embodiments so that those skilled in the art may better understand the aspects of the present disclosure. Those skilled in the art will appreciate that they may readily use the present disclosure as a basis for designing or modifying other processes and structures for carrying out the same purposes and/or achieving the same advantages of the embodiments introduced herein. Those skilled in the art will also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a gate structure on first and second channel structures;
a source/drain (S/D) structure on the first and second channel structures, wherein the S/D structure is at a first side of the gate structure;
a first contact structure on the first channel structure, wherein the first S/D contact structure is at a second side of the gate structure opposite to the first side;
a second contact structure on the second channel structure at the second side of the gate structure; and
a third contact structure on the S/D structure at the first side of the gate structure.

2. The semiconductor device of claim 1, wherein the first contact structure is separated from the second contact structure.

3. The semiconductor device of claim 1, further comprising a gate contact structure on the gate structure.

4. The semiconductor device of claim 3, wherein the gate contact structure extends over the first and second channel structures.

5. The semiconductor device of claim 1, wherein a ratio of a thickness of the S/D structure to a height of the first and second channel structures ranges from about 0.25 to about 0.5.

6. The semiconductor device of claim 1, further comprising a third channel structure, wherein:
the S/D structure is on the third channel structure;
the gate structure is on the third channel structure; and
a first distance between the second and third channel structures is equal to a second distance between the first and second channel structures.

7. The semiconductor device of claim 1, further comprising third and fourth channel structures, wherein:
the S/D structure is on the third and fourth channel structures;
the gate structure is on the third and fourth channel structures; and
a first distance between the second and third channel structures is greater than a second distance between the first and second channel structures.

8. The semiconductor device of claim 1, wherein:
the first channel structure has a first width;
the second channel structure has a second width different from the first width;
the first and second channel structures comprise a dopant; and
a concentration of the dopant in the first channel structure is different from a concentration of the dopant in the second channel structure.

9. The semiconductor device of claim 1, further comprising:
an additional gate structure on the first and second channel structures at the first side of the gate structure, wherein the S/D structure is between the gate structure and the additional gate structure;
a fourth contact structure on the first channel structure, wherein the fourth contact structure and the S/D structure are on opposite sides of the additional gate structure; and
a fifth contact structure on the second channel structure, wherein the fifth contact structure is separated from the fourth contact structure, and wherein the fifth contact structure and the S/D structure are on opposite sides of the additional gate structure.

10. A semiconductor device, comprising:
a first transistor on a substrate, wherein the first transistor comprises:
a first channel structure on the substrate;
a first gate structure on the first channel structure;
a first source/drain (S/D) structure on the first channel structure at a first side of the gate structure; and
a first contact structure on the first channel structure at a second side of the gate structure, wherein the second side is opposite to the first side; and
a second transistor on the substrate, wherein the second transistor comprises:
a second channel structure on the substrate;
a second gate structure on the second channel structure, wherein the second gate structure is in contact with the first gate structure;
a second S/D structure on the second channel structure at the first side of the gate structure, wherein the second S/D structure is in contact with the first S/D structure; and
a second contact structure on the second channel structure at the second side of the gate structure, wherein the second contact structure is separate from the first contact structure.

11. The semiconductor device of claim 10, further comprising a third contact structure on the first and second S/D structures, wherein the third contact structure extends over one or more of the first and second channel structures.

12. The semiconductor device of claim 10, further comprising a gate contact structure on the first and second gate structures, wherein the gate contact structure extends over one or more of the first and second channel structures.

13. The semiconductor device of claim 10, wherein a ratio of a thickness of the first S/D structure to a height of the first channel structure ranges from about 0.25 to about 0.5.

14. The semiconductor device of claim 10, further comprising additional transistors having respective channel structures, wherein:
the first, second, and additional transistors comprise a first number of groups of channel structures;
each group in the first number of groups of channel structures comprises a second number of channel structures; and
a first distance between each group is greater than a second distance between the channel structures in each group.

15. The semiconductor device of claim 14, wherein the first number is equal to or greater than 20 and the second number is between 2 and 22.

16. A method, comprising:
forming a gate structure on first and second channel structures;
forming, at a first side of the gate structure, a source/drain (S/D) structure on the first and second channel structures;
forming, at a second side of the gate structure opposite to the first side, a first contact structure on the first channel structure and a second contact structure on the second channel structure, wherein the first and second contact structures are separated from each other; and
forming a third contact structure on the S/D structure.

17. The method of claim 16, wherein the third contact structure extends over one or more of the first and second channel structures.

18. The method of claim 16, further comprising forming a gate contact structure on the gate structure, wherein the gate contact structure extends over one or more of the first and second channel structures.

19. The method of claim 16, further comprising:
doping the first and second channel structures with a dopant; and
diffusing the dopant along the first and second channel structures.

20. The method of claim 19, wherein doping the first and second channel structures comprises:
forming a mask layer covering the gate structure and the first and second channel structures at the second side of the gate structure;
implanting the dopant in the S/D structure and the first and second channel structures at the first side of the gate structure; and
performing a thermal anneal on the first and second channel structures.
